(19) United States
(12) Patent Application Publication
(10) Pub. No.: US 2026/0293436 A1
(43) Pub. Date: Sep. 24, 2026

(54) DISPLAY PANEL MANUFACTURING APPARATUS AND DISPLAY PANEL MANUFACTURING METHOD

(71) Applicant: Samsung Display Co., LTD., Yongin-si (KR)

(72) Inventor: YEONGHO HA, Yongin-si (KR)

(21) Appl. No.: 19/566,400

(22) Filed: Mar. 13, 2026

(30) Foreign Application Priority Data
Mar. 24, 2025 (KR) 10-2025-0037037

(51) Int. Cl. H10K 59/12

(52) U.S. Cl. CPC H10K 59/1201

(57) ABSTRACT

Provided are a display panel manufacturing apparatus and a display panel manufacturing method. The display panel manufacturing apparatus includes a processing unit which performs an outer lead bonding (OLB) process on a display panel, a panel supply unit which supplies the display panel to the processing unit, and a panel discharge unit which discharges the display panel from the processing unit, wherein the processing unit includes a rotation unit in which the display panel is positioned and which is rotatable about an axis, and a plurality of process areas disposed around the rotation unit. The rotation unit may sequentially supply the display panel to the plurality of process areas.

This application claims priority to Korean Patent Application No. 10-2025-0037037, filed on, March 24, 2024, and all the benefits accruing therefrom under 35 U.S.C. §119, the content of which in its entirety is herein incorporated by reference.

### BACKGROUND

### 1. Field

The present disclosure relates to a display panel manufacturing apparatus and a display panel manufacturing method.

### 2. Description of the Related Art

In general, in portable electronic devices such as mobile phones, laptops, personal digital assistants (PDAs), and navigation devices, various types of high-density semiconductor packages are mounted on a panel and used as components to drive screens and implement characteristics of low-voltage driving, low power consumption, full-color, and the like. Furthermore, in a task of mounting high-density semiconductor packages on a panel, bonding apparatuses with various structures are used to mount a semiconductor package, which is a driving circuit, to be electrically connected to a display panel.

Here, as a technology for manufacturing high-density semiconductor packages, a tape carrier package (TCP) method is a representative method that implements semiconductor chips, which are a plurality of integrated circuit elements, to be mounted on one panel at a high density. Furthermore, recently, a technology such as a chip-on-board (COB), chip-on-glass (COG), or a chip-on-film (COF) has been developed and is being used to mount semiconductor chips.

In the past, in bonding process apparatuses for bonding semiconductor packages to a panel, while a panel is moved along a single conveyor belt, the panel is loaded into a plurality of process operations for the bonding by robots which are capable of picking up/putting down objects. However, in this case, there have been problems in that a large amount of time is incurred for movement teaching between robots and a space occupied by a bonding process apparatus is excessively large.

### SUMMARY

Embodiments of the present disclosure provide a display panel manufacturing apparatus that shortens an amount of time associated with performing and completing an outer lead bonding (OLB) process.

In some aspects, embodiments of the present disclosure provide a display panel manufacturing apparatus that reduces a space occupied by an OLB process.

However, the objects are for illustration, and the objects to be solved by the present disclosure are not limited thereto.

An embodiment of the present disclosure provides a display panel manufacturing apparatus including a processing unit which performs an outer lead bonding (OLB) process on a display panel, a panel supply unit which supplies the display panel to the processing unit, and a panel discharge unit which discharges the display panel from the processing unit, wherein the processing unit includes a rotation unit in which the display panel is positioned and which is rotatable about an axis, and a plurality of process areas disposed around the rotation unit, and the rotation unit sequentially supplies the display panel to the plurality of process areas.

In an embodiment, the plurality of process areas may include an anisotropic conducting film (ACF) attachment unit which attaches an ACF to a side surface of the display panel, a driver integrated circuit (IC) supply unit which supplies a driver IC to a portion of the display panel to which the ACF is attached, a pre-press bonding unit which pre-presses the ACF and the driver IC, a final press bonding unit which finally pre-presses the ACF and the driver IC, and an inspection unit which inspects the display panel on which the OLB process has been performed.

In an embodiment, the driver IC supply unit may include a multi-joint robot.

In an embodiment, the rotation unit may rotate 360˚ about the axis.

In an embodiment, the rotation unit may rotate clockwise and counterclockwise.

In an embodiment, the rotation unit may include a panel transfer unit which moves in a first direction and a second direction perpendicular to the first direction.

In an embodiment, the processing unit may perform the OLB process in a state in which the panel transfer unit extends in the first direction in association with positioning the display panel in the plurality of process areas.

In an embodiment, the panel transfer unit may further sequentially transfer the display panel to the ACF attachment unit, the driver IC supply unit, the pre-press bonding unit, the final press bonding unit, the inspection unit, and the panel discharge unit.

In an embodiment, the display panel supply unit may include a first rail unit which moves the display panel.

In an embodiment, the panel discharge unit may include a second rail unit which moves the display panel.

Another embodiment of the present disclosure provides a display panel manufacturing method using a display panel manufacturing apparatus including a panel supply unit, a panel discharge unit, and a processing unit which comprises a rotation unit, the display panel manufacturing method including supplying, by a panel supply unit, a display panel to a processing unit, performing, by the processing unit, an OLB process on the display panel, and discharging, by a panel discharge unit, the display panel from the processing unit, wherein, in the performing of the OLB process, the rotation unit rotates about an axis (R) in association with performing a plurality of processes.

In an embodiment, the plurality of processes may include attaching, by an ACF attachment unit, an ACF to a side surface of the display panel, supplying, by a driver IC supply unit, a driver IC to the ACF attached to the display panel, pre-pressing, by a pre-press bonding unit, the ACF and the driver IC, finally pressing, by a final press bonding unit, the ACF and the driver IC, and inspecting, by an inspection unit, the display panel on which the OLB process has been performed.

In an embodiment, the supplying of the driver IC may be performed by a multi-joint robot included in the driver IC supply unit.

In an embodiment, the rotation unit may rotate clockwise and counterclockwise the axis in association with performing the plurality of processes.

In an embodiment, the display panel manufacturing method may further include sequentially transferring, by a panel transfer unit included in the rotation unit, the display panel to the pre-press bonding unit, the final press bonding unit, the inspection unit, and the panel discharge unit.

In an embodiment, the sequential transfer may include loading, by the panel transfer unit, the display panel into a processing space in a first direction, and adjusting, by the panel transfer unit, a position of the display panel in a second direction perpendicular to the first direction.

In an embodiment, the inspecting further includes inspecting, by the inspection unit, an alignment of the driver IC attached to the display panel.

In an embodiment, the attaching of the ACF, the supplying of the driver IC, the pre-pressing, the final pressing, and the inspecting may be completed in an amount of time equal to 15 seconds or less.

In an embodiment, a teaching time of the display panel manufacturing apparatus with respect to each of the attaching of the ACF, the supplying of the driver IC, the pre-pressing, the final pressing, and the inspecting may be 30 minutes or less.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view illustrating a display device manufactured through a display manufacturing apparatus according to an embodiment of the present disclosure;

FIG. 2 is a schematic cross-sectional view illustrating an example of a cross section along line I-I’ of FIG. 1;

FIG. 3 is a schematic cross-sectional view illustrating a structure of a pixel;

FIG. 4 is a schematic perspective view illustrating a display panel manufacturing apparatus according to an embodiment of the present disclosure;

FIG. 5 is a schematic perspective view illustrating a modified example of the display panel manufacturing apparatus of FIG. 4;

FIG. 6 is a schematic perspective view illustrating a rotation unit of FIG. 4;

FIG. 7 is a flowchart of a display panel manufacturing method according to an embodiment of the present disclosure;

FIG. 8 is a flowchart of a plurality of processes according to an embodiment of the present disclosure;

FIG. 9 is a block diagram of an electronic device manufactured by using a display panel manufacturing apparatus according to an embodiment of the present disclosure; and

FIG. 10 illustrates schematic views of electronic devices according to various embodiments manufactured according to a display panel manufacturing apparatus according to an embodiment of the present disclosure.

### DETAILED DESCRIPTION

Since the disclosure can apply various transformations and have various embodiments, specific embodiments will be illustrated in the drawings and described in detail in the detailed description. Effects and features of the present disclosure, and methods for achieving them will become clear with reference to the embodiments described herein in detail together with the drawings. However, the present disclosure is not limited to the embodiments disclosed below and may be implemented in various forms.

In the following embodiments, the terms first, second, and the like do not have limited meaning but are used for the purpose of distinguishing one component from another component.

In the following embodiments, the expressions used in the singular such as “a,” “an,” and “the” are intended to include the plural forms as well, unless the context clearly indicates otherwise.

In the following embodiments, it will be understood that the terms such as “including,” “comprising,” and “having” specify the presence of stated features or components, but do not preclude the presence or addition of one or more other features or components.

In the following embodiments, when a unit, an area, a component, or the like is positioned on or above another part, the present disclosure includes not only a case in which the unit, the area, the component, or the like is positioned directly above the other part, but also a case in which other units, other areas, other component, or the like may be positioned therebetween.

In the following embodiments, unless the terms “connecting” or “coupling” are clearly different in context, the terms “connecting” or “coupling” do not necessarily mean direct and/or fixed connection or coupling of two members, but do not exclude a member positioned between the two members.

The term “adjacent” used herein may refer to cases in which elements are relatively close to but spaced apart from one another. In some aspects, elements described as adjacent to one another may be neighboring one another but spaced apart by a predetermined distance.

In the drawings, components may be exaggerated or reduced in size for convenience of description. For example, the sizes and/or thicknesses of the respective components illustrated in the drawings are arbitrarily illustrated for convenience of description, and thus one or more embodiments are not necessarily limited thereto.

Hereinafter, example embodiments of the present disclosure will be described in detail with reference to the accompanying drawings, wherein like reference numerals refer to the same or corresponding components throughout the drawings, and a redundant description thereof will be omitted.

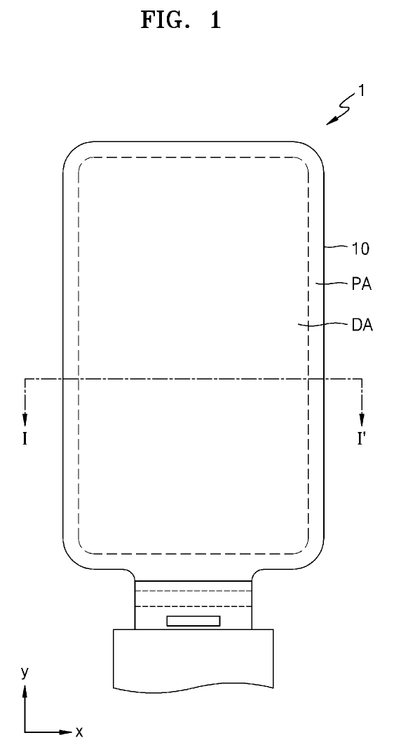

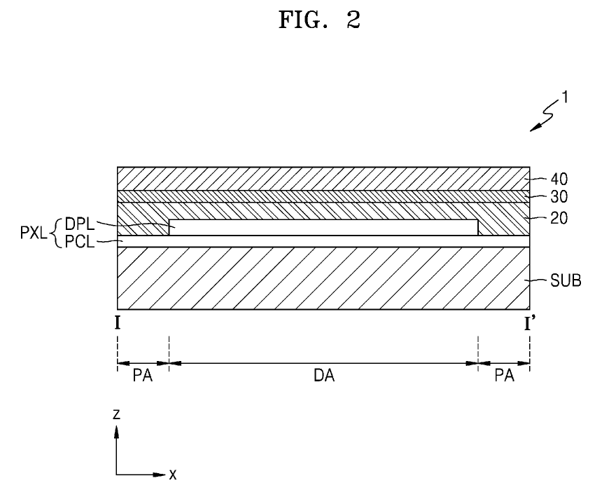

FIG. 1 is a schematic perspective view illustrating a display device 1 manufactured through a display manufacturing apparatus according to an embodiment of the present disclosure. FIG. 2 is a schematic cross-sectional view illustrating an example of a cross section along line I-I’ of FIG. 1.

Referring to FIG. 1, the display device 1 manufactured through the display manufacturing apparatus according to an embodiment of the present disclosure may include a display area DA and a peripheral area PA. The peripheral area PA is disposed around the display area DA to surround the display area DA. Various interconnects and driving circuits that transmit electrical signals to be applied to the display area DA may be positioned in the peripheral area PA. The display device 1 may provide a certain image by using light emitted from a plurality of pixels disposed in the display area DA. Although not illustrated, the display device 1 may be bent in a partial area of the peripheral area PA by including a bending area.

The display device 1 may be a display device such as an organic light-emitting display device 1, an inorganic light-emitting display device, an inorganic electroluminescent (EL) display device, or a quantum dot light-emitting display device. Hereinafter, the organic light-emitting display device 1 will be described as an example. The display device 1 may be implemented as various types of electronic devices such as a mobile phone, a laptop, and a smart watch.

As illustrated in FIG. 2, the display device 1 may include a substrate SUB, a pixel layer PXL on the substrate SUB, an encapsulating member 20 sealing the pixel layer PXL, a touch sensing layer 30 on the encapsulating member 20, and a cover layer 40 on the touch sensing layer 30 which are sequentially stacked in a thickness direction (Z direction).

The substrate SUB may include a glass material or a polymer resin. For example, the substrate SUB may include a glass material including SiO₂ as a main component or may include various materials having flexible or bendable properties, for example, a resin such as reinforced plastic. Although not illustrated, the substrate SUB may be bent in a partial area of the peripheral area PA by including a bending area.

The pixel layer PXL may be disposed on the substrate SUB. The pixel layer PXL may include a display element layer DPL including display elements disposed for each pixel and a pixel circuit layer PCL including pixel circuits and insulating layers disposed for each pixel. The display element layer DPL may be disposed on an upper layer of the pixel circuit layer PCL, and a plurality of insulating layers may be disposed between the pixel circuit and the display element. Some interconnects and insulating layers of the pixel circuit layer PCL may extend to the peripheral area PA.

The encapsulating member 20 may be a thin film encapsulating layer. The thin film encapsulating layer may include at least one inorganic encapsulating layer and at least one organic encapsulating layer. In an example in which the display device 1 includes the substrate SUB including a polymer resin, and the encapsulating member 20 which is a thin film encapsulating layer including an inorganic encapsulating layer and an organic encapsulating layer, the flexibility of the display device 1 may be improved.

The touch sensing layer 30 may acquire coordinate information according to an external input, for example, a touch event.

The touch sensing layer 30 may include sensing electrodes (or touch electrodes) and signal lines (trace lines) connected to the sensing electrodes. The touch sensing layer 30 may detect an external input by using a mutual cap method or/and a self-cap method.

As an embodiment, the touch sensing layer 30 may be a capacitive type. In an example in which the cover layer 40 is touched, a change in capacitance may occur between a sensing electrode and a counter electrode of the touch sensing layer 30, and the change in capacitance may be detected to determine whether a corresponding portion has been touched.

The touch sensing layer 30 may be formed directly on a display panel or may be formed separately and then coupled to the display panel through an adhesive layer such as an optical clear adhesive (OCA). For example, the touch sensing layer 30 may be formed consecutively after a process of forming the display panel, and in this case, the adhesive layer may not be interposed between the touch sensing layer 30 and the display panel.

The cover layer 40 may be disposed on the touch sensing layer 30 to protect the display device 1.

The cover layer 40 may have flexible properties. The cover layer 40 may include polymethyl methacrylate, polydimethylsiloxane, polyimide, acrylate, polyethylen terephthalate, polyethylen naphthalate, or the like. However, one or more embodiments are not limited thereto, and the cover layer 40 may include various materials such as a metal material, and in some cases, thin metal foil of steel use stainless (SUS) may be used.

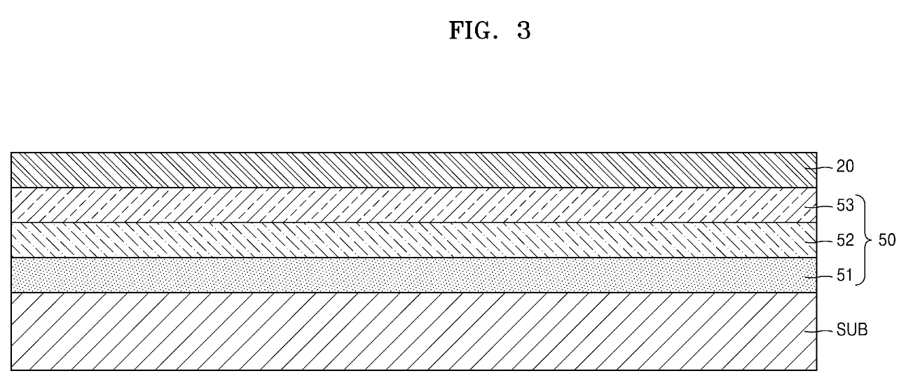

FIG. 3 is a schematic cross-sectional view illustrating a structure of a pixel.

Referring to FIG. 3, one pixel may include a pixel circuit and an organic light-emitting diode 50 electrically connected to the pixel circuit.

Each pixel may emit, for example, red, green, blue, or white light through the organic light-emitting diode 50.

The organic light-emitting diode 50 may include a pixel electrode 51, an intermediate layer 52, and a counter electrode 53.

The pixel electrode 51 may be disposed on a substrate SUB. Here, the pixel electrode 51 is not limited to being disposed directly on an upper surface of the substrate SUB, and at least one insulating layer or electrode layer may be further disposed between the pixel electrode 51 and the substrate SUB.

The pixel electrode 51 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 51 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof.

The intermediate layer 52 includes an emission layer. The emission layer may include a polymer or low-molecular-weight organic material that emits light with a certain color. In an embodiment, the intermediate layer 52 may include a first functional layer disposed below the emission layer and/or a second functional layer disposed on the emission layer. The first functional layer and/or the second functional layer may include a layer that is integrally formed on a plurality of pixel electrodes 51 or may include a layer patterned to correspond to each of the plurality of pixel electrodes 51.

The first functional layer may be a single layer or a multi-layer. In an example in which the first functional layer includes a polymer material, the first functional layer may be a hole transport layer (HTL) that is a single layer structure and may include poly-3,4-ethylene-dihydroxy thiophene (PEDOT) or polyaniline (PANI). In an example in which the first functional layer includes a low-molecular-weight material, the first functional layer may include a hole injection layer HIL and the HTL.

In some embodiments, the second functional layer may be omitted. In an example in which the first functional layer and the emission layer include a polymer material, the second functional layer may be formed to improve the properties of the organic light-emitting diode 50. The second functional layer may be a single layer or a multi-layer. The second functional layer may include an electron transport layer (ETL) and/or an electron injection layer (EIL).

The counter electrode 53 is disposed to face the pixel electrode 51 with the intermediate layer 52 interposed between the counter electrode 53 and the pixel electrode 51. The counter electrode 53 may include a conductive material with a low work function. For example, the counter electrode 53 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 53 may further include a layer including ITO, IZO, ZnO, or In₂O₃ on the (semi)transparent layer including the above-described material.

The counter electrode 53 may be disposed on the intermediate layer 52. The counter electrode 53 may be integrally formed in a plurality of organic light-emitting diodes 50 in a display area DA and may face the plurality of pixel electrodes 51.

A thin film encapsulating layer as an encapsulating member 20 may be disposed on the counter electrode 53. The thin film encapsulating layer serves to protect the organic light-emitting diode 50 from external moisture, oxygen, or the like. The thin film encapsulating layer may have a multilayer structure. For example, the thin film encapsulating layer may include a plurality of inorganic layers and a plurality of organic layers. Since the thin film encapsulating layer is formed to have a multilayer structure, even when a crack occurs in the thin film encapsulating layer, the crack may be prevented from being connected between each inorganic layer and each organic layer. Thus, it is possible to prevent or minimize the formation of a path through which external moisture or oxygen penetrates into the display area DA. In other embodiments, the number of organic layers, the number of inorganic layers, and a stacking order thereof may be changed.

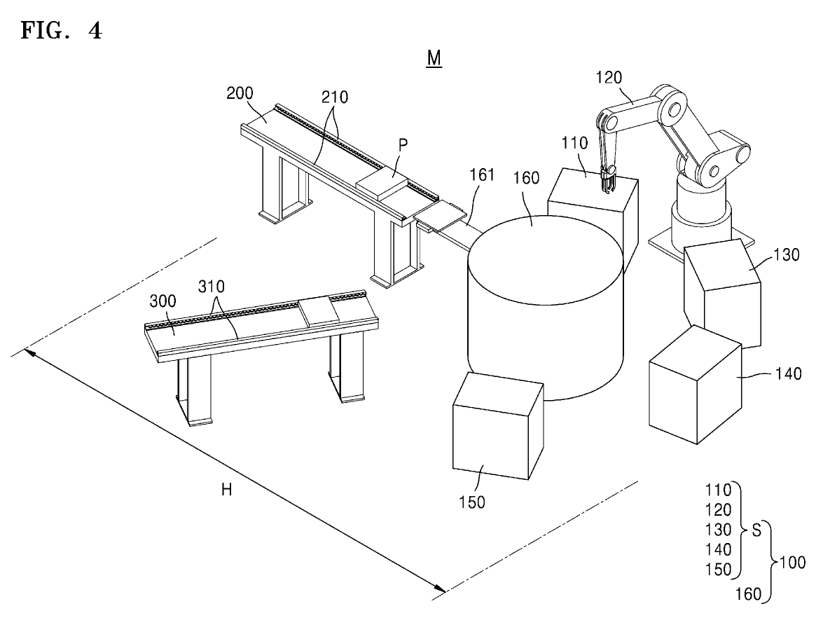

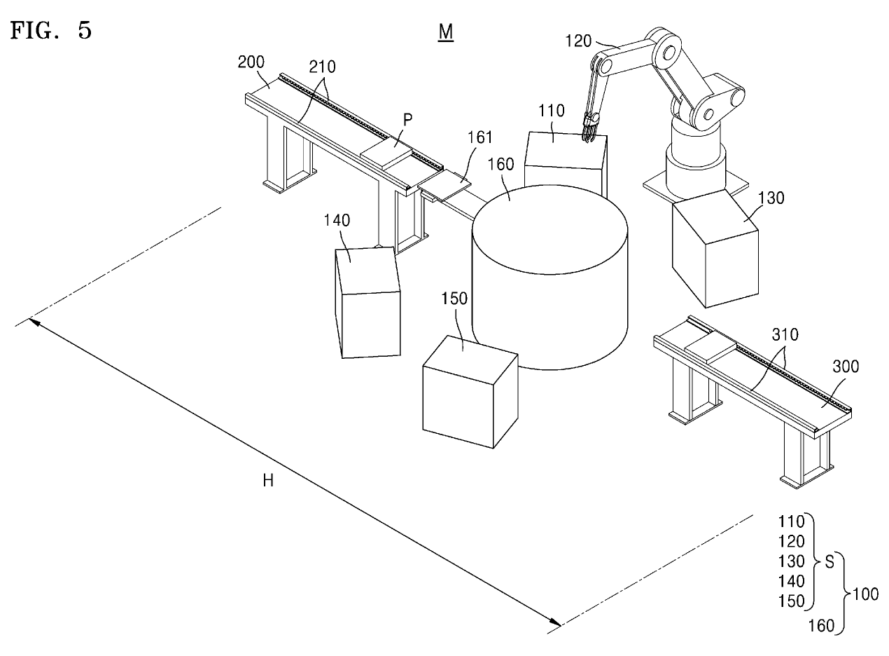

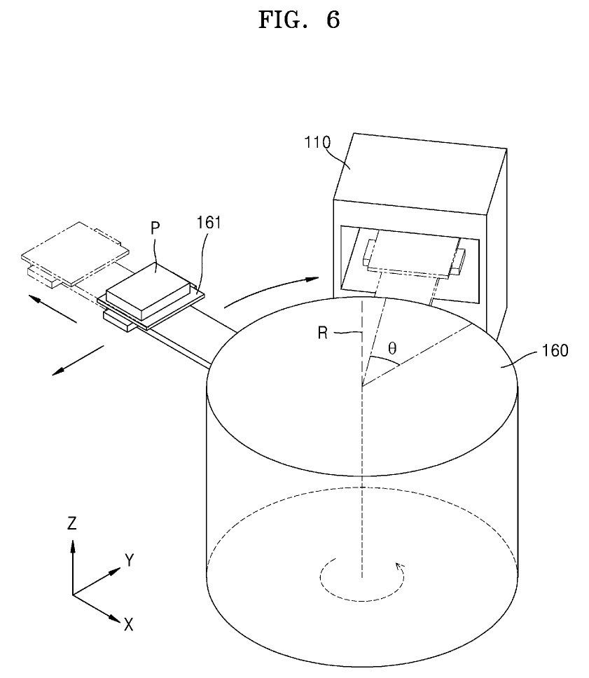

FIG. 4 is a schematic perspective view illustrating a display panel manufacturing apparatus M according to an embodiment of the present disclosure. FIG. 5 is a schematic perspective view illustrating a modified example of the display panel manufacturing apparatus M of FIG. 4. FIG. 6 is a schematic perspective view illustrating a rotation unit 160 of the display panel manufacturing apparatus M of FIG. 4.

Referring to FIGS. 4 to 6, the display panel manufacturing apparatus M includes a processing unit 100, a panel supply unit 200, and a panel discharge unit 300.

The processing unit 100 performs an outer lead bonding (OLB) process on a display panel P.

The OLB process refers to an operation of attaching a driver integrated circuit (driver IC) to one side portion of the display panel P using an adhesive film. Here, the adhesive film may include an anisotropic conductive film (ACF).

The panel supply unit 200 may supply the display panel P to the processing unit 100.

The panel supply unit 200 may supply the display panel P to the processing unit 100 such that a bonding operation may be performed on a side portion of the display panel P.

Specifically, in order for a bonding operation to be performed on any one side surface of a lateral side surface and a vertical side surface of the display panel P, the panel supply unit 200 may horizontally supply the display panel P such that the lateral side surface or the vertical side surface corresponds to an ACF attachment unit 110.

The panel supply unit 200 may include a first rail unit 210 that moves the display panel P.

As a method by which the panel supply unit 200 moves the display panel P, a typical method such as a movement method using a rail or a movement method using a conveyor belt may be used, but embodiments of the present disclosure are not limited thereto.

The panel supply unit 200 may move the display panel P to the processing unit 100 through the first rail unit 210, and specifically, may move the display panel P to a panel transfer unit 161.

Here, when the display panel P is moved from the first rail unit 210 to the panel transfer unit 161, a typical object transfer method may be used, and specifically, various object transfer methods such as a vacuum suction method, a transfer method using a robot arm, a transfer method using an air suspension, or a magnetic field may be used, but embodiments of the present disclosure are not limited thereto.

The panel discharge unit 300 discharges the display panel P from the processing unit 100.

As a method by which the panel discharge unit 300 moves the display panel P from the processing unit 100, a typical method such as a movement method using a rail or a movement method using a conveyor belt may be used, but embodiments of the present disclosure are not limited thereto.

The panel discharge unit 300 may include a second rail unit 310 that moves the display panel P.

The panel discharge unit 300 may move the display panel P from the processing unit 100 through the second rail unit 310, and specifically, the display panel P may be received from the panel transfer unit 161 and moved.

Here, when the display panel P is moved from the second rail unit 310 to the panel transfer unit 161, a typical object transfer method may be used, and specifically, various object transfer methods such as a vacuum suction method, a transfer method using a robot arm, or a transfer method using an air suspension or a magnetic field may be used, but embodiments of the present disclosure are not limited thereto.

Here, the panel supply unit 200 and the panel discharge unit 300 may be disposed adjacent to each other. In an example in which the panel supply unit 200 and the panel discharge unit 300 are disposed adjacent to each other, the rotation unit 160 may rotate about an axis R in a single direction (for example, clockwise or counterclockwise) such that, when the OLB process is performed on the display panel P, a movement distance of the display panel P from the panel supply unit 200 to the panel discharge unit 300 may be minimized, and an overall length H of the display panel manufacturing apparatus M may be reduced.

As another example, as illustrated in FIG. 5, the panel supply unit 200 and the panel discharge unit 300 may be positioned at opposite sides with respect to the rotation unit 160.

Since a plurality of process areas S may be disposed around the rotation unit 160, an overall length H’ of the display panel manufacturing apparatus M may be reduced as compared to when existing process areas are arranged in a line. In some aspects, when the panel supply unit 200 and the panel discharge unit 300 are disposed at opposite sides with respect to the rotation unit 160, the arrangement of the plurality of process areas S for performing a process may be free, and the connection with other process equipment connected to the panel supply unit 200 and the panel discharge unit 300 before and after the OLB process may be simplified.

The processing unit 100 includes the rotation unit 160 and the plurality of process areas S.

The display panel P may be positioned on the rotation unit 160, and the rotation unit 160 may be rotated in place about an axis R.

The plurality of process areas S are disposed around the rotation unit 160.

The rotation unit 160 sequentially supplies the display panel P to the plurality of process areas S.

Specifically, the rotation unit 160 may rotate about an axis R and may transfer the display panel P to the plurality of process areas S disposed around the rotation unit 160, and the plurality of process areas S may perform the OLB process on the received display panel P.

The rotation unit 160 may rotate 360˚ about an axis R.

After the display panel P is transferred from the panel supply unit 200 to the panel transfer unit 161, the rotation unit 160 may rotate about an axis R (θ direction) to transfer the display panel P to the ACF attachment unit 110, a driver IC supply unit 120, a pre-press bonding unit 130, a final press bonding unit 140, an inspection unit 150, and the panel discharge unit 300. Accordingly, the panel supply unit 200 and the panel discharge unit 300 may be positioned adjacent to each other.

When the rotation unit 160 rotates in a single direction (for example, clockwise or counterclockwise), a time taken for movement between the plurality of process areas S may be minimized such that a time of the OLB process may be considerably shortened.

The rotation unit 160 may rotate clockwise and counterclockwise.

After the display panel P is transferred from the panel supply unit 200 to the panel transfer unit 161, the rotation unit 160 may rotate about an axis R clockwise (θ direction) to transfer the display panel P to the ACF attachment unit 110, the driver IC supply unit 120, and the pre-press bonding unit 130, and may rotate about an axis R counterclockwise (θ direction) to transfer the display panel P to the final press bonding unit 140, the inspection unit 150, and the panel discharge unit 300. Accordingly, the panel supply unit 200 and the panel discharge unit 300 may be positioned opposite to each other.

When the rotation unit 160 rotates clockwise and counterclockwise, the panel supply unit 200 and the panel discharge unit 300 may be positioned opposite to each other such that the position design of an apparatus for the OLB process may be simplified.

The rotation unit 160 may include the panel transfer unit 161 that moves in a first direction (X direction) and a second direction (Y direction) perpendicular to the first direction.

The panel transfer unit 161 may extend in the first direction (X direction) and position the display panel P on the ACF attachment unit 110, the driver IC supply unit 120, the pre-press bonding unit 130, the final press bonding unit 140, or the inspection unit 150.

In this case, the panel transfer unit 161 may load the display panel P into a processing space, in which a plurality of processes are performed, in the first direction (X direction), and may finely adjust a position in the second direction (Y direction).

The panel transfer unit 161 may extend in the first direction (X direction) and position the display panel P in the process area, and in this state, the OLB process may be performed.

That is, in a state in which the panel transfer unit 161 extends in the first direction (X direction) in the ACF attachment unit 110, the driver IC supply unit 120, the pre-press bonding unit 130, the final press bonding unit 140, or the inspection unit 150 in association with positioning the display panel P in each process area, each process may be performed.

In some aspects, the panel transfer unit 161 may sequentially transfer the display panel P to the ACF attachment unit 110, the driver IC supply unit 120, the pre-press bonding unit 130, the final press bonding unit 140, the inspection unit 150, and the panel discharge unit 300.

The plurality of process areas S may include the ACF attachment unit 110, the driver IC supply unit 120, the pre-press bonding unit 130, the final press bonding unit 140, and the inspection unit 150.

The ACF attachment unit 110 attaches an anisotropic conducting film (ACF) to a side surface of the display panel P.

Here, the side surface of the display panel P refers to a lateral or vertical side surface of the display panel P.

The ACF refers to an anisotropic conducting film, is an adhesive film widely used in electronic packaging and display panel manufacturing, and has properties in which a current flows in a single direction (for example, a Z direction) and does not flow in the other directions (for example, the X direction and Y direction).

The driver IC supply unit 120 supplies a driver IC to a portion of the display panel P to which the ACF is attached.

The driver IC may be a semiconductor chip that amplifies and controls a signal in an electronic device to operate specific components. The driver IC may be attached to the display panel P to control the operation of a display.

The pre-press bonding unit 130 may pre-press the ACF and the driver IC.

Here, pre-pressing refers to an operation of temporarily applying pressure before final pressing of the ACF and the driver IC. Through the pre-pressing, positions of the display panel P and the driver IC may be fixed before final pressing.

In some aspects, the pre-press bonding unit 130 may include a pre-press tool (not illustrated) that applies pressure to the display panel P, the ACF applied onto the side surface of the display panel P, and the driver IC, and a sensing unit (not illustrated) that determines a position at which the pressure is applied.

The final press bonding unit 140 finally presses the ACF and the driver IC.

In some aspects, the final press bonding unit 140 may include a final pressure tool (not illustrated) that applies pressure to the display panel P, the ACF applied onto the side surface of the display panel P, and the driver IC, and a sensing unit (not illustrated) that determines a position at which the pressure is applied.

The driver IC supply unit 120 may include various mechanical devices capable of transferring a driver IC to the portion of the display panel P, to which the ACF is attached, and specifically may include a multi-joint robot.

Here, the multi-joint robot may refer to a robot that may move three-dimensionally (for example, along an X-axis, a Y-axis, and a Z-axis) about a plurality of rotation axes, and when the driver IC supply unit 120 includes the multi-joint robot, even when the rotation unit 160 rotates along one rotation axis of the rotation axes, a driver IC may be precisely supplied to a position of the display panel P at which the ACF is attached.

The inspection unit 150 inspects the display panel P on which the OLB process has been performed.

The inspection unit 150 may inspect the alignment of the driver IC attached to the display panel P. In some aspects, the inspection unit 150 may include an automatic inspection device.

The length H or H’ of the display panel manufacturing apparatus M may be in a range of 1 m to 10 m or 4 m to 6 m or may be about 4.8 m.

In the past, a length of an OLB process apparatus has been about 15 m or less, but by introducing a turntable method to an OLB process apparatus according to the present disclosure, a space occupied by the OLB process apparatus may be considerably reduced.

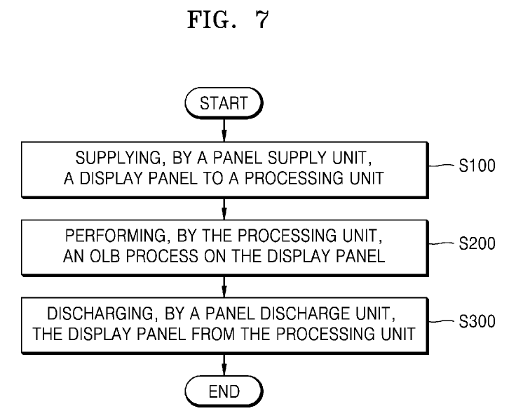

FIG. 7 is a flowchart of a display panel manufacturing method according to an embodiment of the present disclosure.

Referring to FIG. 7, a display panel manufacturing method using a display panel manufacturing apparatus according to the present disclosure includes operation S100 of supplying, by a panel supply unit 200, a display panel P to a processing unit 100, operation S200 of performing, by the processing unit 100, an OLB process on the display panel P, and operation S300 of discharging, by a panel discharge unit 300, the display panel P from the processing unit 100.

In operation S100 of supplying the display panel, the panel supply unit 200 may supply the display panel P to the processing unit 100 through a first rail unit 210.

Specifically, the display panel P may be supplied to a panel transfer unit 161 of the processing unit 100.

In operation S200 of performing the OLB process, a rotation unit 160 rotates about an axis R in association with performing a plurality of processes.

The rotation unit 160 may rotate 360˚ about an axis R.

The rotation unit 160 may rotate 360˚ about the axis R in association with sequentially performing the plurality of processes, and thus the display panel manufacturing method may perform and complete the plurality of processes associated with the OLB process in a reduced amount of time. That is, the rotation unit 160 performs the OLB process while rotating 360˚ in a single direction rather than rotating in two directions (e.g., clockwise and counterclockwise), and thus movement between a plurality of process areas S in the OLB process is minimized, thereby obtaining an effect of minimizing a total time taken for the OLB process.

The rotation unit 160 may rotate clockwise and counterclockwise.

The rotation unit 160 may rotate in one direction (for example, clockwise) as well as the other direction (for example, counterclockwise). Accordingly, the panel supply unit 200 and the panel discharge unit 300 may be disposed opposite to each other, and when the panel supply unit 200 and the panel discharge unit 300 are disposed opposite to each other, process equipment may be simplified.

The panel transfer unit 161 included in the rotation unit 160 may sequentially transfer the display panel P to a pre-press bonding unit 130, a final press bonding unit 140, an inspection unit 150, and the panel discharge unit 300.

The sequential transfer may include an operation of loading, by the panel transfer unit 161, the display panel P into a processing space in a first direction (X direction), and an operation of adjusting, by the panel transfer unit 161, a position of the display panel P in a second direction (Y direction) perpendicular to the first direction (X direction).

That is, when the panel transfer unit 161 sequentially transfers the display panel P to the pre-press bonding unit 130, the final press bonding unit 140, the inspection unit 150, and the panel discharge unit 300, the panel transfer unit 161 may move in the first direction (X direction) and may finely adjust the position in the second direction (Y direction) perpendicular to the first direction to load the display panel P into the processing space, thereby performing each of the processes of the OLB process.

Accordingly, the panel transfer unit 161 may transfer the display panel P to each processing space by performing the operation of loading, by the panel transfer unit 161, the display panel P into the processing space in the first direction (X direction), and the operation of adjusting, by the panel transfer unit 161, the position of the display panel P in the second direction (Y direction).

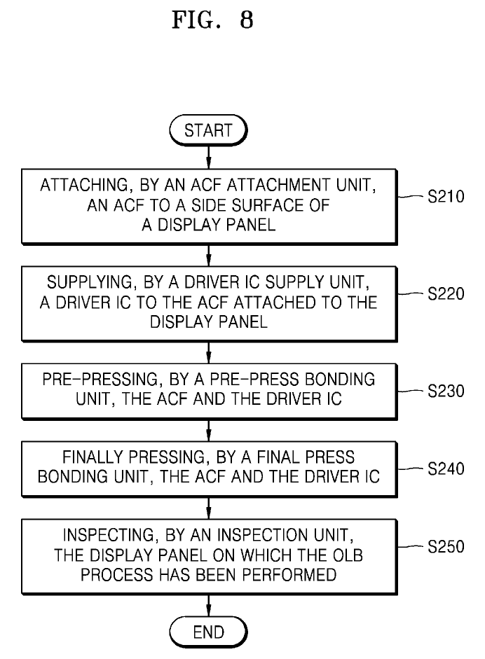

FIG. 8 is a flowchart of a plurality of processes according to an embodiment of the present disclosure.

Referring to FIG. 8, the plurality of processes include operation S210 of attaching, by an ACF attachment unit 110, an ACF to a side surface of a display panel P, operation S220 of supplying, by a driver IC supply unit, a driver IC to the ACF attached to the display panel P, operation S230 of pre-pressing, by a pre-press bonding unit 130, the ACF and the driver IC, operation S240 of finally pressing, by a final press bonding unit 140, the ACF and the driver IC, and operation S250 of inspecting, by an inspection unit 150, the display panel P on which the OLB process has been performed.

In operation S210 of attaching the ACF, as the ACF attachment unit 110 attaches the ACF to the side surface of the display panel P, an adhesive material that may attach an electronic device such as a semiconductor chip to the display panel P is input.

Operation S220 of supplying the driver IC may be an operation of supplying, by the driver IC supply unit, the driver IC to the ACF attached to the display panel P. As the ACF is attached to the side surface of the display panel P through operation S100 of attaching the ACF to the display panel P, and the driver IC is supplied to the side surface of the display panel P to which the ACF is attached, the display panel P and the driver IC may be bonded to each other through the ACF.

Operation S220 of supplying the driver IC may be performed by a multi-joint robot.

The multi-joint robot may be a robot that may freely move in a three-dimensional space commonly usable in a processing space of a factory, and after the driver IC is fixed through the multi-joint robot, the driver IC may be supplied to the ACF attached to the side surface of the display panel P.

Operation S230 of pre-pressing the ACF and the driver IC is an operation of pre-pressing, by the pre-press bonding unit 130, the ACF and the driver IC, wherein the driver IC and the display panel P are coupled to each other through the ACF. Operation S230 is an operation of temporarily fixing a position of the driver IC attached to the display panel P by including an operation of performing pre-pressing before operation S240 of finally pressing the ACF and the driver IC.

Operation S240 of finally pressing the ACF and the driver IC is an operation of finally pressing, by the final press bonding unit 140, the ACF and the driver IC and is an operation of coupling the driver IC and the display panel P to each other through the ACF. Operation S240 of finally pressing the ACF and the driver IC may be repeatedly performed a plurality of times.

Operation S250 of inspecting the display panel P may be an operation of inspecting, by the inspection unit 150, the alignment of the driver IC attached to the display panel P through the OLB process. In an example in which the driver IC of the display panel P is misaligned, problems such as electrical contact defects, screen defects, circuit damage, and image quality degradation may occur.

In some aspects, in operation S250 of inspecting the display panel P, errors in the OLB process may be automatically inspected through an automated test and tool.

In the display panel manufacturing method of the present disclosure, operation S210 of attaching the ACF, operation S220 of supplying the driver IC, operation S230 of pre-pressing the ACF and the driver IC, operation S240 of finally pressing the ACF and the driver IC, and operation S250 of inspecting the display panel P may be completed in an amount of time equal to 15 seconds or less.

In an OLB process of a related art, an operation of attaching an ACF, an operation of supplying a driver IC, an operation of pre-pressing the ACF and the driver IC, an operation of finally pressing the ACF and the driver IC, and an operation of inspecting a display panel has been completed in an amount of time equal to 30 seconds or more, resulting in a problem of lack of speed in the OLB process.

Accordingly, in a display panel manufacturing apparatus M according to the present disclosure, the rotation unit 160 may rotate about an axis R to transfer the display panel P, and thus each operation of a process of performing the OLB process may be completed in a reduced amount of time equal to 15 seconds or less.

In the display panel manufacturing method of the present disclosure, a teaching time of the display panel manufacturing apparatus M with respect to performing and completing operation S210 of attaching the ACF, operation S220 of supplying the driver IC, operation S230 of pre-pressing the ACF and the driver IC, operation S240 of finally pressing the ACF and the driver IC, and operation S250 of inspecting the display panel P may be 30 minutes or less.

A teaching time of equipment refers to an amount of time associated with programming and operating industrial equipment according to a specific task. Additionally, the teaching time of equipment also includes the time taken for teaching the operation procedures of the equipment based on the operator’s commands and/or training. That is, the teaching time of equipment refers to all the time in which a process of setting a path, operation, conditions, and the like is completed such that industrial equipment may perform a desired task.

In an OLB process of a related art, teaching times of OLB equipment with respect to each of an operation of attaching an ACF, an operation of supplying a driver IC, an operation of pre-pressing the ACF and the driver IC, an operation of finally pressing the ACF and the driver IC, and an operation of a display panel has been 1 hour or more, resulting in a problem of lack of speed in the OLB process.

Accordingly, in the display panel manufacturing apparatus M according to the present disclosure, the rotation unit 160 may rotate about an axis R to transfer the display panel P, and thus a teaching time of the display panel manufacturing apparatus M with respect to each operation of a process of performing the OLB process may be reduced to 30 minutes or less.

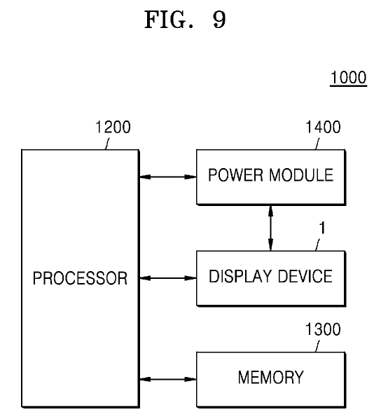

FIG. 9 is a block diagram of an electronic device 1000 manufactured by using a display panel manufacturing apparatus according to an embodiment of the present disclosure.

Referring to FIG. 9, the electronic device 1000 manufactured by using the display panel manufacturing apparatus according to an embodiment of the present disclosure may include a display device 1, a processor 1200, a memory 1300, and a power module 1400.

The display device 1 may be the above-described display device 1 manufactured by using a substrate etching apparatus 10 or a substrate etching method.

The display device 1 may receive data from the processor 1200 to provide visual information. The display device 1 may be the above-described display device 1 according to embodiments of the present disclosure.

The processor 1200 may include at least one of a central processing unit (CPU), an application processor (AP), a graphic processing unit (GPU), a communication processor (CP), an image signal processor (ISP), and a controller. For example, the processor 1200 may operate by executing at least one program.

The memory 1300 may store data information supportive of the operation of the processor 1200 or the display device 1. As an example, the memory 1300 may store the at least one program. In an example in which the processor 1200 executes an application stored in the memory 1300, an image data signal and/or an input control signal may be transmitted to the display device 1, and the display device 1 may process a received signal to output image information through a display screen.

The power module 1400 may include a power supply module such as a power adapter or a battery device, and a power conversion module that converts power supplied by the power supply module to generate power for the operation of the electronic device 1000. As an example, the power module 1400 may supply power to the display device 1.

At least one of the components of the above-described electronic device 1000 may be included in the above-described display device 1 according to the embodiments. In some aspects, some of the individual modules functionally included in one module may be included in the display device 1, and others may be provided separately from the display device 1.

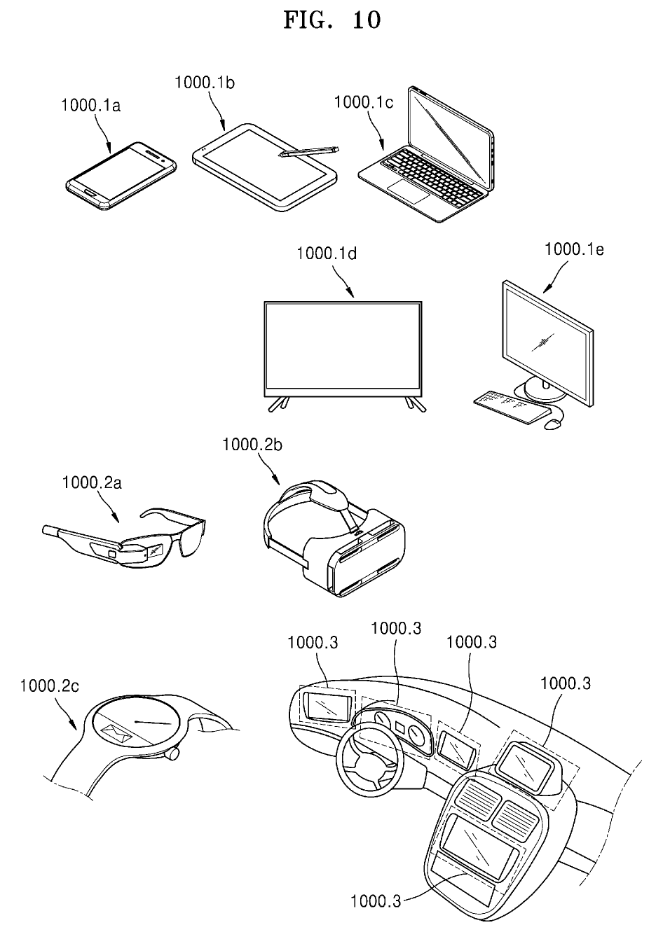

FIG. 10 illustrates schematic views of electronic devices according to various embodiments manufactured by using a display panel manufacturing apparatus according to an embodiment of the present disclosure.

Referring to FIG. 10, various electronic devices to which a display device manufactured according to the display panel manufacturing apparatus of the present disclosure is applied may include not only image display electronic devices such as a smartphone 1000.1a, a tablet personal computer (PC) 1000.1b, a laptop 1000.1c, a television (TV) 1000.1d, and a desk monitor 1000.1e, but also wearable electronic devices including display devices such as smart glasses 1000.2a, a head-mounted display 1000.2b, and a smart watch 1000.2c, and vehicle electronic devices 1000.3 including display devices such as a center information display (CID) and a room mirror display disposed on an instrument panel, a center fascia, or a dashboard of a vehicle.

Embodiments of the present disclosure may provide a display panel manufacturing apparatus and a display panel manufacturing method in which the amount of time associated with performing and completing an OLB process is shortened.

In some aspects, embodiments of the present disclosure provide a display panel manufacturing apparatus and a display panel manufacturing method in which a space occupied by an OLB process is reduced.

However, the effects are for illustration, and the effects of the present disclosure are not limited thereto.

Each of the embodiments described herein may be implemented independently, but of course, the structures of each embodiment may be applied in combination to other embodiments.

While the present disclosure has been described with reference to embodiments illustrated in the drawings, this is illustrative. It is to be understood that various equivalent modifications and variations of the embodiments may be made by a person having an ordinary skill in the art without departing from the spirit and scope of the present disclosure. Therefore, the true technical scope of protection of the disclosure should be determined by the technical spirit of the appended claims. Accordingly, the true technical protection scope of the disclosure should be defined by the technical spirit of the appended claims.

The specific implementations described in the embodiments are examples and do not limit the scope of the embodiments in any method. In some aspects, unless “essential,” “important,” and the like are not specifically mentioned, it may not be a necessary component for the application of the present disclosure.

In the specification (especially in the claims) of the embodiments, the use of the term “the” and similar indicating terms may correspond to both singular and plural. In some aspects, in the case where a range is described in the embodiment, since it includes the disclosure in which the individual values belonging to the range are applied, unless otherwise stated, it is the same as describing each individual value constituting the range in the detailed description. Finally, when there is no explicit or contradictory description of operations constituting the method according to the embodiment, the operations may be performed in a suitable order. The embodiments are not necessarily limited to the order in which the operations are described. The use of all the examples or exemplary terms in the embodiments is for describing the embodiments in detail. Accordingly, the scope of the embodiments may not be limited by the examples or exemplary terms, unless limited by the claims. In some aspects, those skilled in the art may recognize that various modifications, combinations, and changes may be confided according to design conditions and factors within the scope of the appended claims or equivalents thereof.

What is claimed is:

1. A display panel manufacturing apparatus comprising:
a processing unit which performs an outer lead bonding (OLB) process on a display panel;
a panel supply unit which supplies the display panel to the processing unit; and
a panel discharge unit which discharges the display panel from the processing unit,
wherein:
the processing unit comprises:
a rotation unit in which the display panel is positioned and which is rotatable about an axis, and
a plurality of process areas disposed around the rotation unit, and
the rotation unit sequentially supplies the display panel to the plurality of process areas.

2. The display panel manufacturing apparatus of claim 1, wherein the plurality of process areas comprise:
an anisotropic conducting film (ACF) attachment unit which attaches an ACF to a side surface of the display panel;
a driver integrated circuit (IC) supply unit which supplies a driver IC to a portion of the display panel to which the ACF is attached;
a pre-press bonding unit which pre-presses the ACF and the driver IC;
a final press bonding unit which finally pre-presses the ACF and the driver IC; and
an inspection unit which inspects the display panel on which the OLB process has been performed.

3. The display panel manufacturing apparatus of claim 2, wherein the driver IC supply unit comprises a multi-joint robot.

4. The display panel manufacturing apparatus of claim 1, wherein the rotation unit rotates 360˚ about the axis.

5. The display panel manufacturing apparatus of claim 1, wherein the rotation unit rotates clockwise and counterclockwise.

6. The display panel manufacturing apparatus of claim 2, wherein the rotation unit comprises a panel transfer unit which moves in a first direction and a second direction perpendicular to the first direction.

7. The display panel manufacturing apparatus of claim 6, wherein the processing unit performs the OLB process in a state in which the panel transfer unit extends in the first direction in associated with positioning the display panel in the plurality of process areas.

8. The display panel manufacturing apparatus of claim 6, wherein the panel transfer unit further sequentially transfers the display panel to the ACF attachment unit, the driver IC supply unit, the pre-press bonding unit, the final press bonding unit, the inspection unit, and the panel discharge unit.

9. The display panel manufacturing apparatus of claim 2, wherein the panel supply unit comprises a first rail unit which moves the display panel.

10. The display panel manufacturing apparatus of claim 2, wherein the panel discharge unit comprises a second rail unit which moves the display panel.

11. A display panel manufacturing method using a display panel manufacturing apparatus comprising a panel supply unit, a panel discharge unit, and a processing unit which comprises a rotation unit, the display panel manufacturing method comprising:
supplying, by the panel supply unit, a display panel to the processing unit;
performing, by the processing unit, an outer lead bonding (OLB) process on the display panel; and
discharging, by the panel discharge unit, the display panel from the processing unit,
wherein, in the performing of the OLB process, the rotation unit rotates about an axis in association with performing a plurality of processes.

12. The display panel manufacturing method of claim 11, wherein the plurality of processes comprise:
attaching, by an anisotropic conducting film (ACF) attachment unit, an ACF to a side surface of the display panel;
supplying, by a driver integrated circuit (IC) supply unit, a driver IC to the ACF attached to the display panel;
pre-pressing, by a pre-press bonding unit, the ACF and the driver IC;
finally pressing, by a final press bonding unit, the ACF and the driver IC; and
inspecting, by an inspection unit, the display panel on which the OLB process has been performed.

13. The display panel manufacturing method of claim 12, wherein the supplying of the driver IC is performed by a multi-joint robot comprised in the driver IC supply unit.

14. The display panel manufacturing method of claim 11, wherein the rotation unit rotates 360˚ about the axis in association with performing the plurality of processes.

15. The display panel manufacturing method of claim 11, wherein the rotation unit rotates clockwise and counterclockwise in association with performing the plurality of processes.

16. The display panel manufacturing method of claim 12, further comprising sequentially transferring, by a panel transfer unit comprised in the rotation unit, the display panel to the pre-press bonding unit, the final press bonding unit, the inspection unit, and the panel discharge unit.

17. The display panel manufacturing method of claim 16, wherein the sequential transfer comprises:
loading, by the panel transfer unit, the display panel into a processing space in a first direction; and
adjusting, by the panel transfer unit, a position of the display panel in a second direction perpendicular to the first direction.

18. The display panel manufacturing method of claim 12, wherein:
the inspecting further comprises inspecting, by the inspection unit, an alignment of the driver IC attached to the display panel.

19. The display panel manufacturing method of claim 12, wherein the attaching of the ACF, the supplying of the driver IC, the pre-pressing, the final pressing, and the inspecting is completed in an amount of time equal to 15 seconds or less.

20. The display panel manufacturing method of claim 12, wherein a teaching time of the display panel manufacturing apparatus with respect to each of the attaching of the ACF, the supplying of the driver IC, the pre-pressing, the final pressing, and the inspecting is 30 minutes or less.
